(19) United States
(12) Patent Application Publication
(10) Pub. No.: US 2019/0195569 A1
(43) Pub. Date: Jun. 27, 2019

(54) WICK STRUCTURE AND LOOP HEAT PIPE USING SAME

(71) Applicant: Asia Vital Components Co., Ltd., New Taipei City (TW)

(72) Inventor: Bor-Bin Tsai, New Taipei City (TW)

(21) Appl. No.: 16/288,218

(22) Filed: Feb. 28, 2019

Related U.S. Application Data
(63) Continuation of application No. 15/415,878, filed on Jan. 26, 2017.

(51) Int. Cl. F28D 15/04; H01L 23/427; F28F 1/24

(52) U.S. Cl. CPC F28D 15/043; F28F 1/24; F28D 15/046; H01L 23/427

(57) ABSTRACT

A wick structure and a loop heat pipe using same are disclosed. The loop heat pipe includes an evaporation chamber, the wick structure and a condensate line. The wick structure is disposed in the evaporation chamber. The evaporation chamber has an outlet and an inlet. The wick structure has a main body, and a plurality of grooves is axially formed on an outer peripheral surface of the main body. The grooves respectively have an open side and a closed side. The open side has a width smaller than that of the closed side. The grooves having the above configuration enable the loop heat pipe to have increased vapor-liquid circulation efficiency.

The present application is a continuation of U.S. patent application Ser. No. 15/415,878, filed on Jan. 26, 2017.

### FIELD OF THE INVENTION

The present invention relates to a wick structure and a loop heat pipe using same. More particularly, the present invention relates to a loop heat pipe having a wick structure that has a plurality of grooves formed thereon to serve as vapor passages, and the grooves are configured to respectively have a narrower open side and a wider closed side. With the grooves having the above configuration, the loop heat pipe can have upgraded vapor-liquid circulation efficiency.

### BACKGROUND OF THE INVENTION

The currently available electronic apparatus all have enhanced performance. As a result, electronic elements in the electronic apparatus for signal processing and computing also produce more heat than previous similar electronic elements. The most commonly used heat dissipation elements include heat pipe, heat sink, vapor chamber and so on. These heat dissipation elements are in direct contact with the heat-producing electronic elements to enable further enhanced heat dissipation performance of the electronic elements and prevent the same from burning out due to overheat.

Further, fans can be mounted in the electronic apparatus to enable forced heat dissipation to remove heat from the heat dissipation elements. While fans can indeed upgrade the heat dissipation performance of the electronic apparatus, they are not suitable for use in the electronic apparatus that have a very limited internal space. Therefore, space is also an important factor to be carefully considered when designing the heat dissipation elements.

Based on the concept of vapor-liquid circulation in a heat pipe, a loop heat pipe structure in the form of a loop module has been developed. The loop heat pipe is formed by combining an evaporation chamber with a condensing unit using a pipe connected to between them. The advantage of the loop heat pipe is having its own heat dissipation unit to provide better evaporation and condensation circulation effect. The evaporation chamber has a wick structure disposed therein for storing the liquid-phase working fluid that flows back into the evaporation chamber. The wick structure is provided with a plurality of grooves, in and along which the vapor-phase working fluid flows. The evaporation chamber has at least one surface in contact with a heat source to absorb and transfer heat produced by the heat source to the working fluid stored in the wick structure, the working fluid in the wick structure is therefore heated and evaporated. The vapor-phase working fluid flows through the grooves into the pipe connected to between the evaporation chamber and the condensing unit to finally spread in the condensing unit. The vapor-phase working fluid passing through the condensing unit is then condensed into liquid-phase working fluid again and flows back into the evaporation chamber to complete one cycle of vapor-liquid circulation in the loop heat pipe.

In the evaporation chamber, the liquid-phase working fluid is adsorbed to the wick structure having grooves. The grooves respectively have an open side in contact with an inner wall surface of the evaporation chamber. The heat absorbed by the evaporation chamber is transferred from the wall thereof to the areas of the wick structure in contact with the wall of the evaporation chamber to thereby heat the wick structure. When the wick structure reaches a temperature high enough for the liquid-phase working heat to evaporate from the grooved surface of the wick structure, the vapor-phase working fluid flows through the grooves and is guided out of the evaporation chamber into a vapor passage to complete one phase transition of the working fluid from the liquid phase into the vapor phase. Conventionally, the grooves formed on the surface of the wick structure all have a square or a rectangular cross-sectional shape. With this design, the overall contact area between the wick structure and the evaporation chamber is reduced, which is disadvantageous to the transfer of heat to the wick structure and produces relatively high thermal resistance.

### SUMMARY OF THE INVENTION

A primary object of the present invention is to solve the problems in the conventional heat dissipation elements by providing a wick structure that has an increased contact area with an inner wall surface of an evaporation chamber to enable reduced thermal resistance during heat conduction.

Another object of the present invention is to provide a loop heat pipe that includes a wick structure having an increased contact area with an inner wall surface of an evaporation chamber of the loop heat pipe to enable reduced thermal resistance during heat conduction.

To achieve the above and other objects, the wick structure according to the present invention includes a main body.

The main body of the wick structure has a plurality of groove axially formed on an outer peripheral surface thereof. The grooves respectively have an open side and a closed side, and the open side has a width smaller than that of the closed side.

To achieve the above and other objects, the loop heat pipe according to the present invention includes an evaporation chamber, a wick structure, a condensate line and a work fluid.

The evaporation chamber has an outlet and an inlet located at two opposite ends thereof.

The wick structure is disposed in the evaporation chamber and includes a main body.

The main body has a plurality of groove axially formed on an outer peripheral surface thereof. The grooves respectively have an open side and a closed side, and the open side has a width smaller than that of the closed side.

The condensate line has a first end and a second end, which are connected to the outlet and the inlet, respectively, of the evaporation chamber.

The working fluid is filled in the evaporation chamber.

The present invention is characterized by improving the configuration of the vapor passages or grooves formed on the wick structure to increase the contact area between the wick structure and the inner wall surface of the evaporation chamber of the loop heat pipe and accordingly reduce the thermal resistance during heat conduction.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view of an embodiment of a wick structure according to the present invention;

FIG. 2 is a first cross-sectional view of a main body of the wick structure of FIG. 1;

FIG. 3A is a second cross-sectional view of the main body of the wick structure of FIG. 1;

FIG. 3B is a third cross-sectional view of the main body of the wick structure of FIG. 1;

FIG. 3C is a perspective view of another embodiment of the wick structure according to the present invention;

FIG. 4 is an assembled perspective view of a preferred embodiment of a loop heat pipe according to the present invention;

FIG. 5 is an assembled sectional view of the loop heat pipe of FIG. 4; and

FIG. 6 is a sectional view showing the loop heat pipe of FIG. 4 in use.

### DETAILED DESCRIPTION OF THE PREFERRED EMBODIMENTS

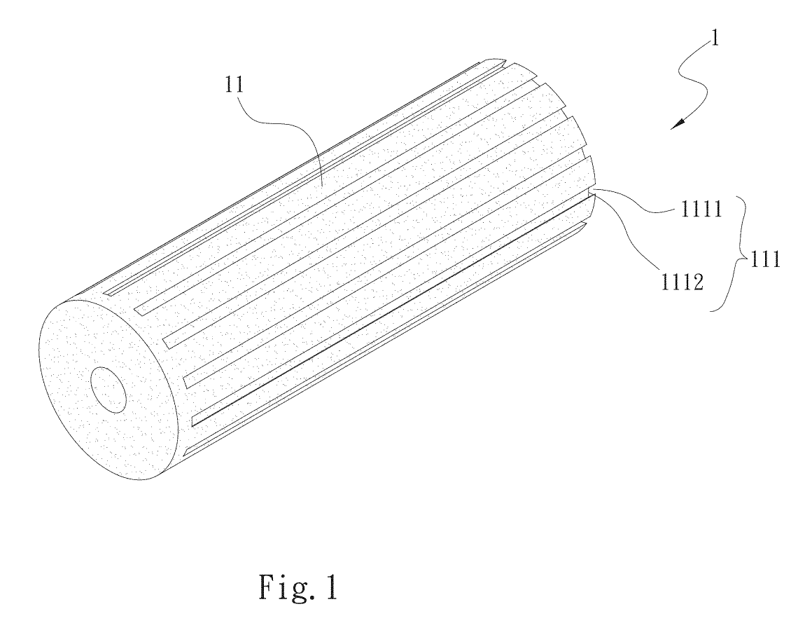

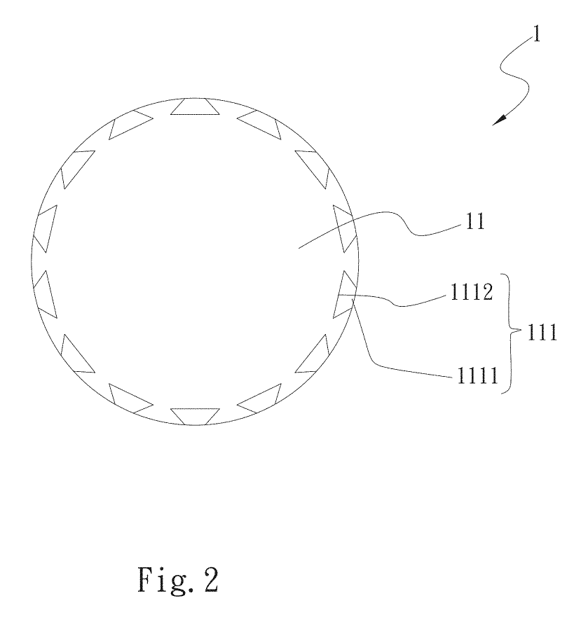

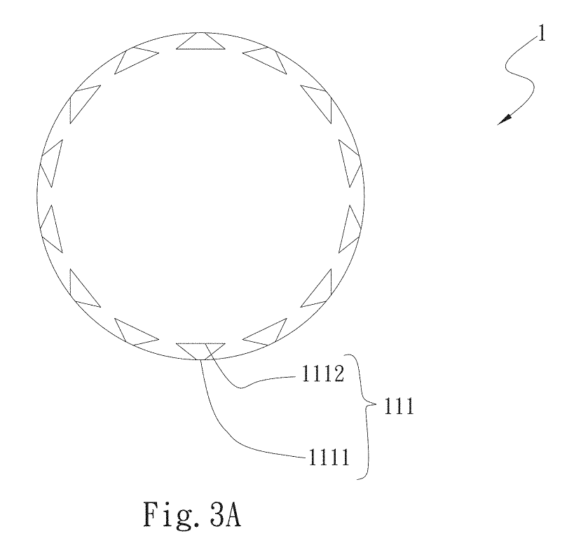

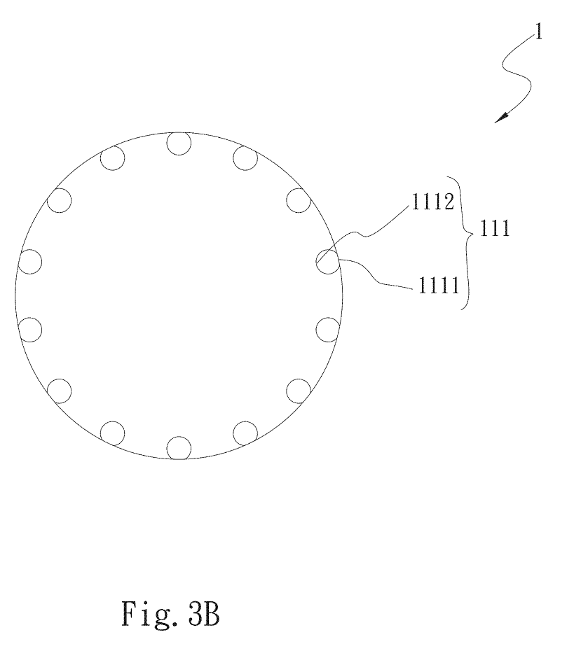

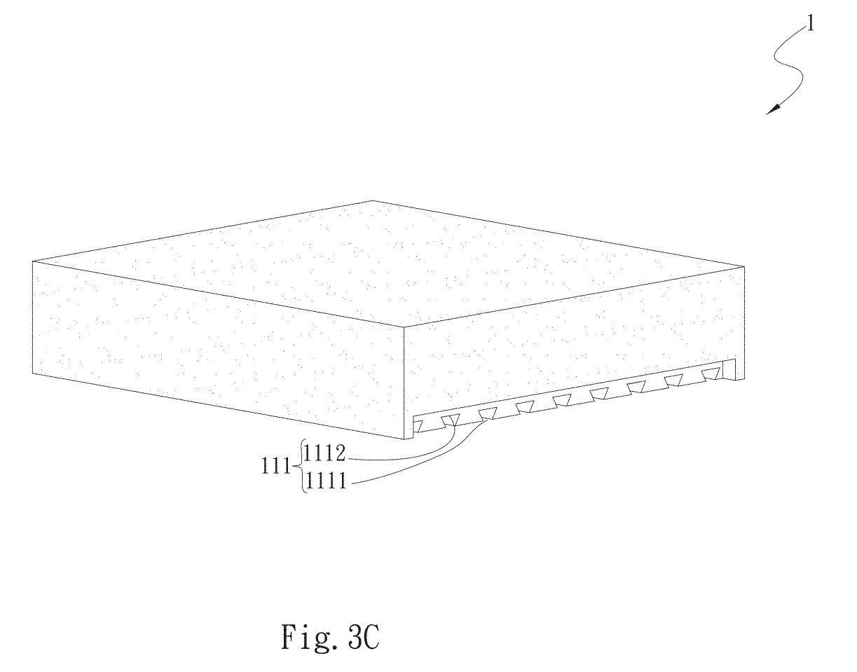

Please refer to FIG. 1 that is a perspective view of a first embodiment of a wick structure 1 according to the present invention, and to FIGS. 2, 3A and 3B that show some possible cross-sectional shapes for the wick structure 1 of FIG. 1. As shown, the wick structure 1 of the present invention includes a main body 11.

The main body 11 has a plurality of grooves 111, which are formed and axially extended on an outer peripheral surface of the main body 11. The grooves 111 respectively have an open side 1111 and a closed side 1112. The open side 1111 has a width smaller than that of the closed side.

The main body 11 is made of a sintered powder material. That is, the main body is formed by sintering a type of metal powder and is therefore a porous wick structure. After the wick structure 1 is formed, the main body 11 can be mechanically processed to form the axially extended grooves 111. Alternatively, when manufacturing the main body 11 by sintering the metal powder, positions for forming the grooves 111 are reserved in advance, so that the grooves 111 are formed on the main body 11 when the sintering process is completed. In the illustrated preferred embodiment as shown in FIG. 1, the main body 11 is a cylindrical body. However, it is understood the main body 11 is not necessarily limited to a cylindrical body. In other embodiments, the main body 11 can be in the form of a rectangular body, as shown in FIG. 3C, or can be a three-dimensional structural body in any geometrical configuration. The main body 11 is not limited to any specific configuration, so long as its configuration can match the shape of an evaporation chamber of a loop heat pipe.

For example, the grooves 111 may respectively have a cross-sectional shape of an up-side-down trapezoid as shown in FIG. 2, or an up-side-down triangle as shown in FIG. 3A, or an ohm symbol Ω as shown in FIG. 3B.

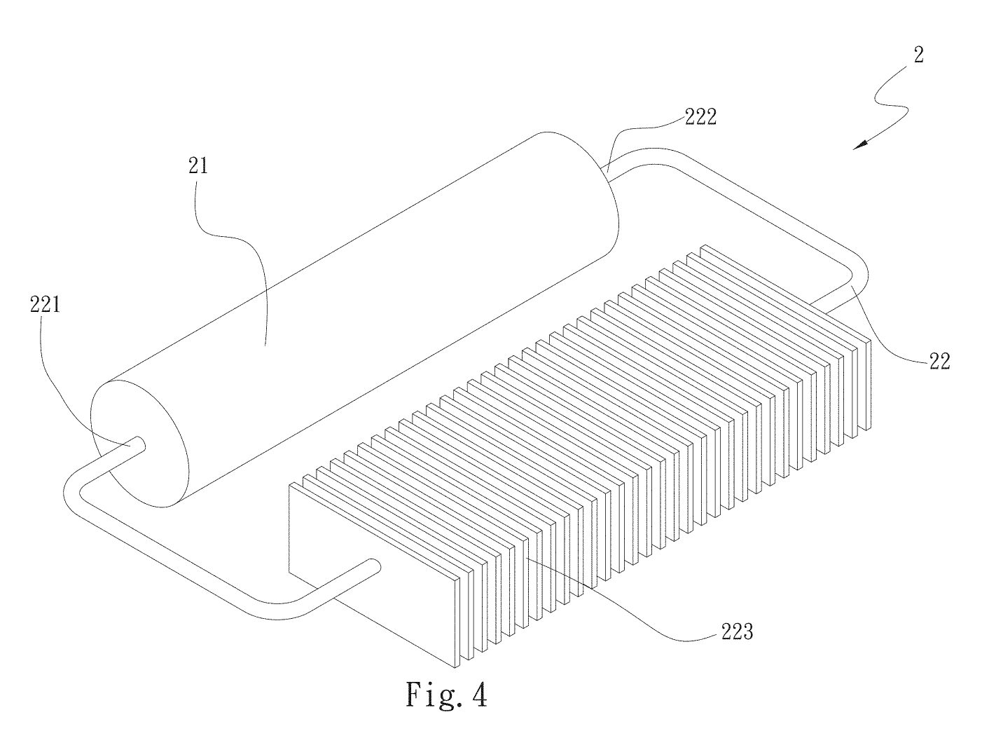

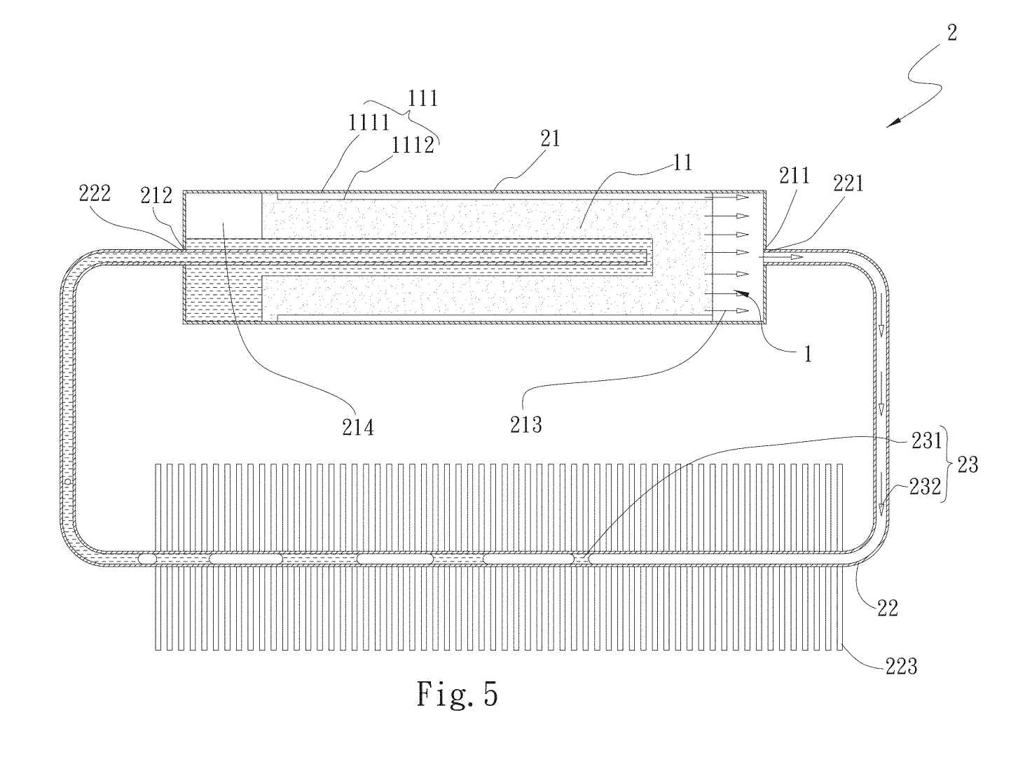

Please refer to FIGS. 4 and 5, which are assembled perspective and sectional views, respectively, of a preferred embodiment of a loop heat pipe 2 according to the present invention. As shown, the loop heat pipe 2 includes an evaporation chamber 21, a wick structure 1, a condensate pipe 22 and a working fluid 23. Since the wick structure 1 for the loop heat pipe 2 is the same as the wick structure 1 described above with reference to FIGS. 1, 2 and 3A to 3C, it is not repeatedly described herein.

The evaporation chamber 21 has an outlet 211 and an inlet 212, which are located at a front and a rear end, respectively, of the evaporation chamber 21. The evaporation chamber 21 can have a round, a square or a flat rectangular cross section.

The wick structure 1 is disposed in the evaporation chamber 21, and includes a main body 11 having a plurality of grooves 111, which are formed and axially extended on an outer peripheral surface of the main body 11. The grooves 111 respectively have an open side 1111 and a closed side 1112. The open side 1111 has a width smaller than that of the closed side 1112.

The condensate line 22 has a first end 221 and a second end 222, which are connected to the outlet 211 and the inlet 212, respectively, of the evaporation chamber 21. The condensate line 22 is extended through a plurality of radiating fins 223, such that the radiating fins 223 are sequentially fixed on and spaced along the condensate line 22 to enable increased condensing efficiency. In an operable embodiment, the radiating fins 223 can be replaced with a plurality of radiating pipes. The working fluid 23 is filled in the evaporation chamber 21. Part of the working fluid 23 is in the liquid phase. Some of the liquid-phase working fluid 231 is remained in the condensate line 22 when the loop heat pipe 2 is not in use.

The open sides 1111 of the grooves 111 of the wick structure 1 are in flat contact with an inner wall surface of the evaporation chamber 21. The evaporation chamber 21 further has a vapor cavity 213 and a compensation chamber 214. The vapor cavity 213 and the compensation chamber 214 are defined between the evaporation chamber 21 and the main body 11 of the wick structure 1. Since the wick structure 1 is disposed in a middle section of the evaporation chamber 21, an end portion of the evaporation chamber 21 that is located adjacent to the inlet 212 is defined as the compensation chamber 214, and the other end portion of the evaporation chamber 21 that is located adjacent to the outlet 211 is defined as the vapor cavity 213.

The vapor cavity 213 functions to pre-pressurize the vapor in the evaporation chamber 21 in order to prevent the liquid-phase working fluid 231 from flowing backward into the evaporation chamber 21, enabling the loop heat pipe 2 to maintain good working efficiency and smooth vapor-liquid circulation.

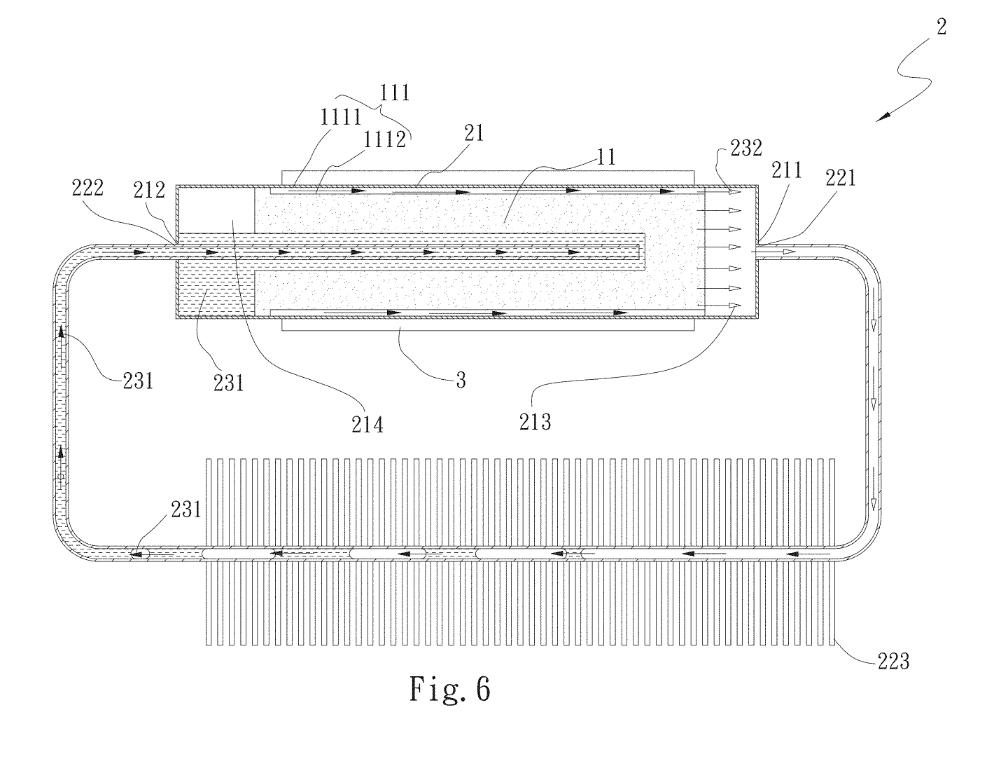

Please refer to FIG. 6, which is a sectional view showing the loop heat pipe 2 of the present invention in use. As shown, the evaporation chamber 21 of the loop heat pipe 2 has at least one side or entire surface in contact with a heat source 3. The evaporation chamber 21 absorbs heat produced by the heat source 3 to thereby heat the liquid-phase working fluid 231 in the evaporation chamber 21. The liquid-phase working fluid 231 stored in the wick structure 1 is heated and finally evaporated to form a vapor-phase working fluid 232. The vapor-phase working fluid 232 flows through the grooves 111 formed on the outer peripheral surface of the wick structure 1 to spread through the condensate line 22 and become condensed at last. In the present invention, to overcome the problem of dry burning of the wick structure 1, the open side 1111 of the groove 111 is designed to have a width smaller than that of the closed side 1112. This means the wick structure 1 according to the present invention has an increased overall volume and an increased contact area with the heat source 3. With this arrangement, the whole wick structure 1 can have increased water content and increased contact area with the evaporation chamber 21 to thereby enable reduced thermal resistance during heat conduction.

More specifically, by giving the open side 1111 of the groove 111 a width smaller than that of the closed side 1112, the wick structure 1 can have an increased contact area with the inner wall surface of the evaporation chamber 21, which also enables an increased heat-transfer area and upgraded vapor-liquid circulation efficiency.

The vapor-phase working fluid 232 outward spread from the grooves 111 into the vapor cavity 213, in which no wick structure 1 is provided. The vapor-phase working fluid 232 in the vapor cavity 213 finally leaves the evaporation chamber 21 via the outlet 211 located at an end of the evaporation chamber 21 into the condensate line 22. The radiating fins 223 fixedly spaced on around the condensate line 22 enable quick condensation of the vapor-phase working fluid 232 in the condensate line 22 into the liquid-phase working fluid 231 again. The liquid-phase working fluid 231 then flows back into the evaporation chamber 21 via the inlet 212, which is provided at another end thereof and closer to the wick structure 1, to complete one cycle of vapor-liquid circulation.

The present invention has been described with a preferred embodiment thereof and it is understood that many changes and modifications in the described embodiment can be carried out without departing from the scope and the spirit of the invention that is intended to be limited only by the appended claims.

What is claimed is:

1. A wick structure, comprising:
a main body having a plurality of grooves and a plurality of non-grooved sections, the plurality of grooves being formed and axially extended on an outer peripheral surface of the main body, the plurality of non-grooved sections being formed between the two grooves; the grooves respectively having an open side being a continuous open face and a closed side being a continuous flat surface, and the open side having a width smaller than that of the closed side; and the non-grooved section having a width larger than that of the closed side of the groove.

2. The wick structure as claimed in claim 1, wherein the main body is made of a sintered powder material.

3. The wick structure as claimed in claim 1, wherein the grooves respectively have a cross-sectional shape selected from the group consisting of an up-side-down trapezoid, an up-side-down triangle and an ohm symbol Ω.

4. A loop heat pipe, comprising:
an evaporation chamber having an outlet and an inlet located at two opposite ends thereof;
a wick structure disposed in the evaporation chamber and including:
a main body having a plurality of grooves and a plurality of non-grooved sections, the plurality of grooves being formed axially extended on an outer peripheral surface of the main body, the plurality of non-grooved sections being formed between the two grooves; the grooves respectively having an open side being a continuous open face and a closed side being a continuous flat surface, and the open side having a width smaller than that of the closed side; and the non-grooved section having a width larger than that of the closed side of the groove;
a condensate line having a first end and a second end, which are connected to the outlet and the inlet, respectively, of the evaporation chamber; and
a working fluid filled in the evaporation chamber and a part of the condensate line.

5. The loop heat pipe as claimed in claim 4, wherein the main body of the wick structure is made of a sintered powder material.

6. The loop heat pipe as claimed in claim 4, wherein the grooves respectively have a cross-sectional shape selected from the group consisting of an up-side-down trapezoid, an up-side-down triangle and an ohm symbol Ω.

7. The loop heat pipe as claimed in claim 4, wherein the open side of the wick structure is in flat contact with an inner wall surface of the evaporation chamber.

8. The loop heat pipe as claimed in claim 4, further comprising a vapor cavity defined between the evaporation chamber and the main body of the wick structure and located adjacent to the outlet of the evaporation chamber.

9. The loop heat pipe as claimed in claim 4, wherein the condensate line has a plurality of radiating fins fitted and spaced around an outer surface of the condensate line.
